(19) United States
(12) Patent Application Publication
(10) Pub. No.: US 2006/0185715 A1
(43) Pub. Date: Aug. 24, 2006

(54) Photovoltaic apparatus including spherical semiconducting particles

(76) Inventors: Milfred Dale Hammerbacher, Waterloo (CA); Mark Douglass Matthews, Richardson, TX (US)

Correspondence Address: PATENT ADMINISTRATOR;KATTEN MUCHIN ROSENMAN LLP, 1025 THOMAS JEFFERSON STREET, N.W., EAST LOBBY: SUITE 700, WASHINGTON, DC, 20007-5201, US

(21) Appl. No.: 10/626,868

(22) Filed: Jul. 25, 2003

(51) Int. Cl. H01L 31/042

(52) U.S. Cl. 136/250

(57) ABSTRACT

A photovoltaic apparatus includes a plurality of approximately spherical photoelectric conversion elements including a second semiconductor layer located outside a first semiconductor layer, for generating photoelectromotive force therebetween. The second semiconductor layer has an opening through which part of the first semiconductor layer is exposed. The apparatus also includes a support having first and second conductors and an insulator disposed between the conductors for electrically insulating the conductors from each other. The support has recesses adjacent to each other, the inside surfaces of which are constituted by the first conductor. The photoelectric conversion elements are disposed in respective recesses so that the elements are illuminated with light reflected by part of the first conductor that constitutes the recess. The first conductor is electrically connected to the second semiconductor layers of the photoelectric conversion elements, and the second conductor is electrically connected to the exposed portions of the first semiconductor layers.

### BACKGROUND OF THE INVENTION

1. Field of the Invention

The present invention relates to a photovoltaic apparatus including substantially spherical semiconductor particles.

In the disclosure herein described, the term “pin junction” is to be construed as including a structure that n-, l- and p-type semiconductor layers are formed on an approximately spherical photoelectric conversion element so as to be arranged in this order outward from the inside of the approximately spherical photoelectric conversion element or inward from the outside.

2. Description of the Related Art

A typical photovoltaic apparatus comprises a photoelectric conversion element composed of a crystal silicon semiconductor wafer. This apparatus is costly because the production of a crystal is complex. Furthermore, manufacturing a semiconductor wafer is not only complex because it includes cutting of a bulk single crystal, slicing, and polishing, but is also wasteful because crystal waste produced by the cutting, slicing, polishing etc. amounts to about 50% by volume or more of the original bulk single crystal.

Another related art photovoltaic apparatus comprises a photoelectric conversion element composed of an amorphous silicon (abbreviated as “a-Si”) thin film, which addresses the above-mentioned problems. Since a thin-film photoelectric conversion layer is formed by the plasma CVD (chemical vapor deposition) method, this related art photovoltaic apparatus has advantages in that certain steps that are conventionally required, such as cutting of a bulk single crystal, slicing, and polishing, are not necessary and a deposited film can be used in its entirety as device active layers. The amorphous silicon photovoltaic apparatus, however, has a drawback in that the semiconductor has a number of crystal defects (i.e., gap states) inside the semiconductor due to the amorphous structure. Also, the amorphous silicon solar battery suffers from the problem that the photoelectric conversion efficiency decreases due to a photo-induced deterioration phenomenon. To address this problem conventionally, a technique of inactivating crystal defects by applying hydrogenation treatment has been developed, whereby the manufacture of such electronic devices as an amorphous silicon solar battery has been realized. Even such a treatment, however, does not entirely eliminate the adverse effects of crystal defects. In, for example, the amorphous silicon solar battery, the photoelectric conversion efficiency still decreases by 15% to 25%.

A recently developed technique for suppressing the photo-induced deterioration has realized a stack-type solar battery in which a photoelectrically active i-type layer is made extremely thin and 2-junction or 3-junction solar cells are used. This technique has succeeded in suppressing the photo-induced deterioration to about 10%. It has become apparent that the degree of photo-induced deterioration decreases when the operation temperature of solar cells is high. Although a module technique in which solar cells are caused to operate in such a condition is now being developed, it does not satisfy all the desired properties and further improvements are required.

Still another related art apparatus that addresses the above problem is disclosed in Japanese Examined Patent Publication JP-B27-54855 (1995). A solar array is formed in the following manner. Spherical particles each having a p-type silicon sphere and an n-type silicon skin are buried in a flat sheet of aluminum foil having holes. The internal p-type silicon spheres are exposed by etching away the n-type silicon skins from the back side of the aluminum foil. The exposed silicon spheres are connected to another sheet of aluminum foil.

In this related art the average thickness of the entire device is reduced by decreasing the outer diameter of the particles. Thus, the cost is reduced by decreasing the amount of high purity silicon used. To increase the conversion efficiency, the light-receiving surface is enlarged and the particles are arranged closer to each other. In summary, a number of particles having a small outer diameter are arranged densely and connected to the sheets of aluminum foil. This makes the connection of the particles to the sheets of aluminum foil complex, with the result that a sufficient cost reduction is not achieved.

Such spherical semiconductor particles are used in order to manufacture a solar array such as the one disclosed in JP-B2 7-54855. In such a solar array, photoelectromotive force generated by applying light to silicon spherical semiconductor particles can be obtained by electrically connecting the silicon spherical semiconductor particles to the metal foil matrix.

### SUMMARY OF THE INVENTION

An object of an aspect of the present invention is to provide a reliable, efficient photovoltaic apparatus that can be mass-produced while the amount of semiconductor material such as high-purity silicon that is used is less than that used in the prior art.

A first aspect of the invention provides a photovoltaic apparatus comprising:

(a) a plurality of photoelectric conversion elements, each being of an approximately spherical shape and including a first semiconductor layer and a second semiconductor layer which is located outside the first semiconductor layer, for generating photoelectromotive force between the first and second semiconductor layers, the second semiconductor layer having an opening through which a portion of the first semiconductor layer is exposed; and

(b) a support including a first conductor, a second conductor, and an insulator disposed between the first and second conductors for electrically insulating the first and second conductors from each other, the support having a plurality of recesses which are arranged adjacent to each other and of which inside surfaces are constituted by the first conductor or a coating formed thereon, the photoelectric conversion elements being disposed in the respective recesses so that the photoelectric conversion elements are illuminated with light reflected by part of the first conductor or coating formed thereon which constitutes the recess, the first conductor being electrically connected to the second semiconductor layers of the photoelectric conversion elements, and the second conductor being electrically connected to the exposed portions of the first semiconductor layers.

The approximately spherical photoelectric conversion elements are disposed in the respective recesses of the support and the inside surfaces of the respective recesses are constituted by the first conductor or the coating formed on the first conductor. Therefore, external light such as sunlight is directly applied to each of the photoelectric conversion elements and sunlight is reflected by the part of the first conductor or coating formed on the part of the first conductor that is the inside surface of the recess.

Since the photoelectric conversion elements are disposed in the respective recesses, intervals are formed in between, that is, their arrangement is not dense. However, the number of photoelectric conversion elements used is decreased, with the result that the amount of high-purity material (e.g., silicon) in the photoelectric conversion elements is reduced and the step of connecting the photoelectric conversion elements to the conductors of the support is made easier:

Further, the recesses are arranged adjacent to each other, whereby external light is reflected by the inside surfaces of the recesses and then applied to the photoelectric conversion elements. Therefore, external light is efficiently used for generation of photoelectromotive force by the photoelectric conversion elements.

The photoelectric conversion elements may be made of a single-crystal, polycrystalline, or amorphous material and may be made of a silicon material, a compound semiconductor material, or the like. The photoelectric conversion elements may have a pn structure, a pin structure, a Schottky barrier structure, a MIS (metal-insulator-semiconductor) structure, a homojunction structure, a heterojunction structure, or the like.

The inside first semiconductor layer is partially exposed through the opening of the outside second semiconductor layer, which makes it possible to take out photoelectromotive force that is generated between the first and second semiconductor layers during application of light. The second semiconductor layers of the respective photoelectric conversion elements disposed in the respective recesses of the support are electrically connected to the first conductor of the support. The exposed portions of the inside first semiconductor layers of the respective photoelectric conversion elements are electrically connected to the second conductor which is formed on the first conductor with the insulator interposed in between. In a structure in which the first conductor and the second conductor extend to form a plane, the photoelectric conversion elements are connected to each other in parallel with the first and second conductors.

The photoelectric conversion element is either a complete sphere or has an outer surface that is approximately a complete spherical surface. In one embodiment, the first semiconductor layer is solid and has an approximately spherical shape. Alternatively, the first semiconductor layer is formed on the outer surface of a core that is prepared in advance. As a further alternative, the approximately spherical first semiconductor layer has a hollow central portion.

In one aspect of the present invention, the photoelectric conversion elements have an outer diameter of about 0.76 mm.

In one aspect of the invention, the recesses of the support have respective openings of a polygon (e.g., honeycomb polygon) of which ones adjacent to each other are continuous, such that each of the recesses narrows toward a bottom thereof, and the first semiconductor layer and second semiconductor layer of each of the photoelectric conversion elements are electrically connected to the second conductor and the first conductor, respectively, at the bottom or in a vicinity thereof of the recess.

In another aspect of the invention, the first conductor has a circular first connection hole formed at the bottom or in a vicinity thereof of the recess and the insulator has a circular second connection hole having a common axial line with the first connection hole. A portion of the photoelectric conversion element in a vicinity of the opening of the second semiconductor layer, fits in the first connection hole. An outer surface portion above the opening of the second semiconductor layer is electrically connected to an end face of the first connection hole of the first conductor or to a portion thereof in the vicinity of the end face. The exposed portion of the first semiconductor layer of the photoelectric conversion element is electrically connected to the second conductor through the second connection hole.

According to still another aspect of the invention, a portion of the photoelectric conversion element in the vicinity of the opening, fits in the first connection hole of the first conductor and the exposed portion of the first semiconductor layer of the photoelectric conversion element is electrically connected to the second conductor through the second connection hole of the insulator of the support. The first conductor and the second conductor of the support are electrically connected to the second semiconductor layer and the first semiconductor layer, respectively, of the photoelectric conversion element.

As for the electrical connection between the second semiconductor layer and the first conductor, a portion, above the opening, of the outer surface of the second semiconductor layer is electrically connected to at least one of the end face of the first connection hole and a portion of the first conductor in the vicinity of the end face. Thus, the portion of the outer surface of the semiconductor layer is connected to at least one of the inner circumferential face of the first connection hole and a portion of the first conductor in the vicinity of and surrounding the first connection hole (see FIG. 1).

In one aspect, shaped aluminum mesh foil forms a plurality of supports. Advantageously, the use of the shaped aluminum foil with substantially spherical photoelectric conversion elements reduces reflective losses of the spherical solar cell. Thus, the number of spheres used per unit area is reduced in comparison to prior-art structures producing comparable power. Thus, the amount of silicon used is reduced. Clearly, the overall power yield per kilogram of Si is improved.

In one aspect of the present invention the photoelectric conversion elements have a pn junction in such a manner that the second semiconductor layer of one conductivity type having a wider optical band gap than the first semiconductor layer having the other conductivity type does is formed outside the first semiconductor layer.

In another aspect of the present invention that the photoelectric conversion elements have a pin junction in such a manner that the first semiconductor layer having one conductivity type, an amorphous intrinsic semiconductor layer, and an amorphous second semiconductor layer of the other conductivity type having a wider optical band gap than that of the first semiconductor layer are arranged outward in this order.

According to an aspect of the present invention, a photovoltaic apparatus is provided using photoelectric conversion elements composed of spherical semiconductor particles. The photovoltaic apparatus using such spherical photoelectric conversion elements generates a high electric power per unit area using as small an amount of single-crystal or polycrystalline semiconductor material as possible.

The invention makes it possible to greatly reduce the used amount of photoelectric conversion element material (in particular, expensive silicon) and to simplify the step of connecting the photoelectric conversion elements to the support by decreasing the number of photoelectric conversion elements, to thereby increase the productivity and reduce the cost. In particular, the use of the photoelectric conversion elements according to the invention makes it possible to realize a manufacturing method capable of saving resources and energy. Sunlight or the like is reflected by the surface of the first conductor or a coating formed thereon that constitutes the inside surface of each recess of the support and resulting reflection light shines on the photoelectric conversion element. In this manner, incident light is utilized effectively. The first conductor or a coating formed thereon serves to not only reflect incident light but also guide currents (the first conductor is connected to the second semiconductor layers of the respective photoelectric conversion elements). Having a simple structure, the support is superior in productivity.

Therefore, it is an aspect of the invention a highly reliable, highly efficient photovoltaic apparatus is provided.

### BRIEF DESCRIPTION OF THE DRAWINGS

The invention will be better understood with reference to the following detailed description taken with reference to the drawings in which:

FIG. 1 is an enlarged sectional view of part of a photovoltaic apparatus according to an embodiment of the present invention;

FIG. 2 is a sectional view showing the structure of the photovoltaic apparatus;

FIG. 3 is an exploded perspective view of the photovoltaic apparatus of FIG. 2;

FIG. 4 is a plan view of part of a support;

FIG. 5 is a sectional view of a photoelectric conversion element that is a version of each photoelectric conversion element before being mounted on the support;

FIG. 6 is a sectional view showing a method for producing an assembly of the photoelectric conversion elements and the support;

FIG. 7 is a sectional view showing a process for forming an opening by cutting each spherical photoelectric conversion element;

FIG. 8 is a simplified perspective view showing a process for placing the photoelectric conversion elements into respective recesses of the support;

FIG. 9 is a perspective view showing how assemblies of the photoelectric conversion elements and the support are connected to each other;

FIG. 10 is an exploded sectional view of peripheral portions and their vicinities of the assemblies shown in FIG. 9;

FIG. 11 is a simplified side view showing how the assemblies are electrically connected to each other;

FIG. 12 is a sectional view showing an electrical connection structure of assemblies that are adjacent to each other according to another embodiment of the invention;

FIG. 13 is a sectional view showing an electrical connection structure of assemblies that are adjacent to each other according to still another embodiment of the invention;

FIG. 14 is a perspective view of a plurality of generally spherical photoelectric conversion elements forming part of an alternative embodiment of a photovoltaic apparatus in accordance with the present invention;

FIG. 15 is a perspective view showing the spherical photoelectric conversion elements of FIG. 14 mounted on a first conductor of a support;

FIG. 16 is a perspective view of generally spherical photoelectric conversion elements mounted on a first conductor of a support, forming part of another embodiment of the photovoltaic apparatus in accordance with the present invention;

FIG. 17 is a perspective view including hidden detail, of the first conductor of the support of FIG. 16;

FIG. 18 is a sectional side view of the generally spherical photoelectric conversion elements in respective recesses of the first conductor of FIG. 16;

FIG. 19 is an another perspective view of the generally spherical photoelectric conversion elements mounted on the first conductor of the support, according to the embodiment of FIG. 16;

FIG. 20 is an enlarged sectional side view of the photovoltaic apparatus according to the embodiment of FIG. 16;

FIG. 21 is a perspective view of the generally spherical photoelectric conversion elements mounted to the first conductor, forming part of yet another embodiment of a photovoltaic apparatus in accordance with the present invention;

FIG. 22 is an enlarged sectional side view of the photovoltaic apparatus according to the embodiment of FIG. 21;

FIG. 23 is a sectional side view of a portion of the photovoltaic apparatus of FIG. 22;

FIG. 24 is a perspective view of the generally spherical photoelectric conversion elements mounted to the first conductor, forming part of yet another embodiment of a photovoltaic apparatus in accordance with the present invention;

FIG. 25 is an alternative perspective view of the generally spherical photoelectric conversion elements mounted on the first conductor, in accordance with the embodiment of FIG. 24;

FIG. 26 is a perspective view of the generally spherical photoelectric conversion elements mounted on the first conductor, similar to the embodiment of FIG. 24, but with a smaller sphere to sphere spacing;

FIG. 27 is a top view of the generally spherical photoelectric conversion elements mounted on the first conductor, in accordance with the embodiment of FIG. 26;

FIG. 28 is a top view of the generally spherical photoelectric conversion elements mounted on the first conductor, in accordance with the embodiment of FIG. 25;

FIG. 29 is a top view of one of the recesses of the first conductor of FIG. 21;

FIG. 30 is a perspective view of the generally spherical photoelectric conversion elements mounted to the first conductor, forming part of still another embodiment of a photovoltaic apparatus in accordance with the present invention;

FIG. 31 is a top perspective view of the first conductor of FIG. 30;

FIG. 32 is a sectional side view of the generally spherical photoelectric conversion elements mounted on the first conductor, in accordance with the embodiment of FIG. 30; and

FIG. 33 is an elevation view showing perforation hole spacing in the first conductor of FIG. 29.

### DETAILED DESCRIPTION OF THE PREFERRED EMBODIMENTS

Now referring to the drawings, preferred embodiments of the invention are described below.

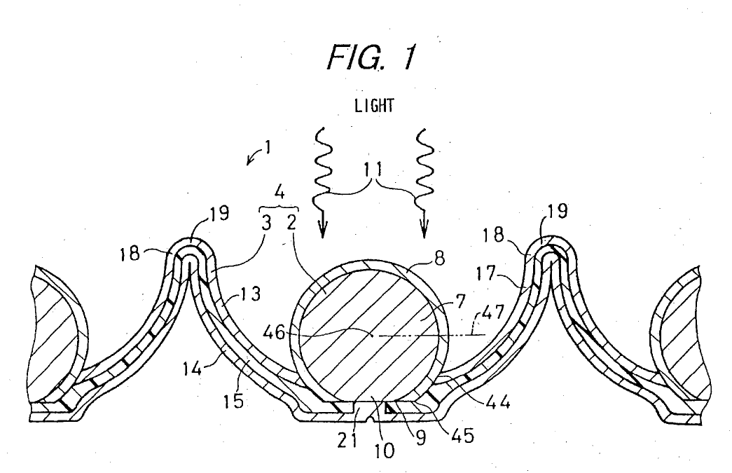

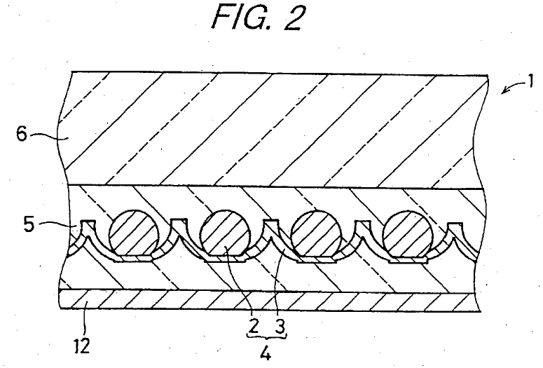

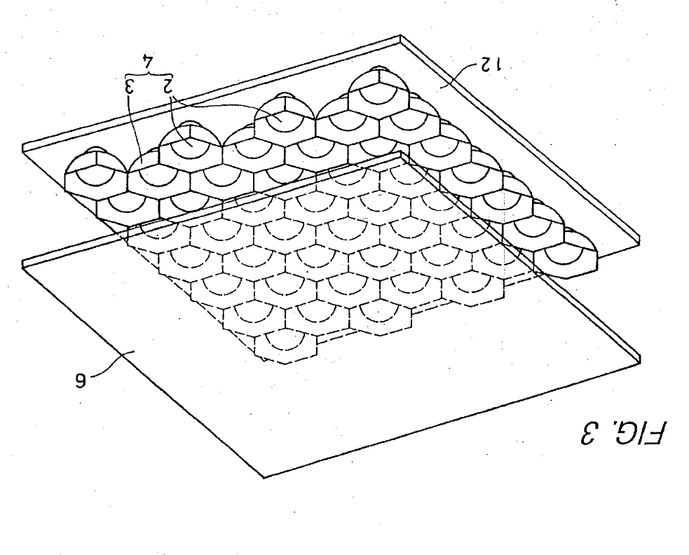

FIG. 1 is an enlarged sectional view of part of a photovoltaic apparatus 1 according to an embodiment of the present invention. FIG. 2 is a sectional view showing the structure of the photovoltaic apparatus 1. FIG. 3 is an exploded perspective view of the photovoltaic apparatus 1 of FIG. 2. The photovoltaic apparatus 1 has the following basic structure. An assembly 4 of a plurality of generally spherical photoelectric conversion elements 2 and a support 3 that is mounted with the photoelectric conversion elements 2 is buried in a filler layer 5 made of a transparent synthetic resin material such as PVB (poly(vinyl butyral)) or EVA (ethylene vinyl acetate). A transparent protective sheet 6 made of polycarbonate or the like is provided on the light source (e.g., sunlight) side of the filler layer 5 and is fixed to it. A waterproof back sheet 12 is fixed to the surface of the filler layer 5 on the opposite side to the protective sheet 6 (bottom side in FIG. 2). As such, the photovoltaic apparatus 1 assumes, as a whole, a flat-plate shape.

Each photoelectric conversion element 2 has a first semiconductor layer 7 and a second semiconductor layer 8 located outside the first semiconductor layer 7. An opening 9 is formed on the second semiconductor layer 8. A portion 10 (a bottom portion in FIG. 1) of the first semiconductor layer 7 is exposed through the opening 9. When light 11 is applied from above in FIG. 1, photoelectromotive force is generated between the first semiconductor layer 7 and the second semiconductor layer 8 of the photoelectric conversion element 2.

The support 3 is conFIG.d in such a manner that an insulator 15 is sandwiched between a first conductor 13 and a second conductor 14. That is, the first conductor 13 and the second conductor 14 are electrically insulated from each other by the insulator 15. Each of the first conductor 13 and the second conductor 14 may be a sheet of aluminum foil or a sheet of another metal. The insulator 15 may be made of a synthetic resin material such as polyimide or some other insulative material. A plurality of recesses 17 are arranged adjacent to each other. The inside surfaces of the recesses 17 are the surface of the first conductor 13. The photoelectric conversion elements 2 are provided at the bottoms of the respective recesses 17.

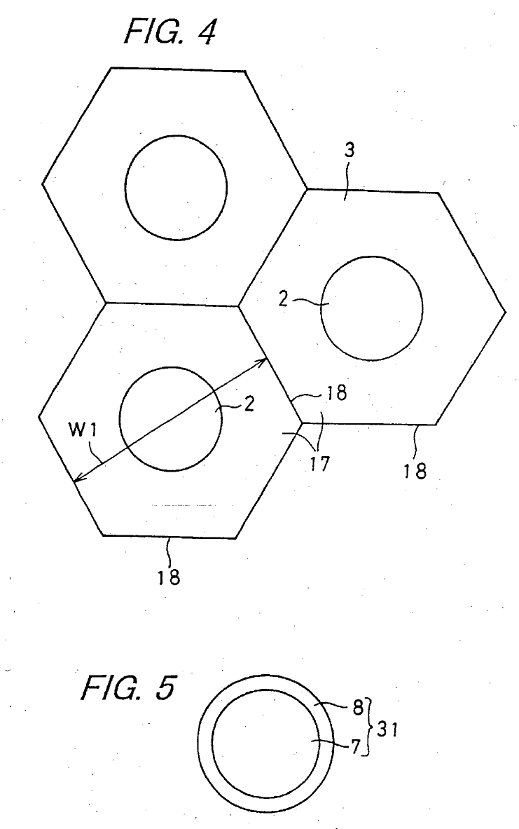

FIG. 4 is a plan view of part of the support 3. In the present embodiment of the invention, openings 18 of the recesses 17 assume polygons. In this embodiment, they assume a honeycomb shape, that is, regular hexagons. According to another embodiment of the invention, the opening 18 of each recess 17 assumes another kind of polygon having three or more apices. In another embodiment of the present invention, the opening 18 of each recess 17 is substantially circular. The length W1 (see FIG. 4) of each opening 18 is about 0.05 inches (1.27 mm), for example. The openings 18 which are adjacent to each other are continuous; that is, the recesses 17 are connected to each other by inverted-U-shaped bent portions 19 (see FIG. 1). This structure makes it possible to accommodate as many recesses 17 as possible in the area that is opposed to the light 11, as well as to cause the inside surfaces of the recesses 17 (i.e., the surface of the first conductor 13) to reflect incident light and guide resulting reflection light to the respective photoelectric conversion elements 2. Therefore, this structure provides a large light-gathering ratio.

Each recess 17 narrows toward the bottom and assumes a parabolic cross-section, for example. At the bottom of each recess 17, the first semiconductor layer 7 of the photoelectric conversion element 2 is electrically connected to the second conductor 14 of the support 3 via a connecting portion 21. At the bottom or its neighborhood of each recess 17, the second semiconductor layer 8 of the photoelectric conversion element 2 is electrically connected to the first conductor 13 of the support 3.

FIG. 5 is a sectional view of a section of a photoelectric conversion element 31 that is similar to the photoelectric conversion element 2 prior to mounting on the support 3. The structure of the photoelectric conversion element 31 shown in section in FIG. 5 is similar to that of each photoelectric conversion element 2 shown in FIG. 1. A spherical first semiconductor layer 7 is made of n-type silicon, amorphous, single-crystal, or polycrystalline silicon. A second semiconductor layer 8 located outside the first semiconductor layer 7 is made of p-type silicon, which may also be amorphous, single-crystal, or polycrystalline silicon. When the optical band gap of the second semiconductor layer 8 is set wider than that of the first semiconductor layer 7 (e.g., the second semiconductor layer 8 is made of p-type a-SiC), wide gap window action can be attained.

According to another embodiment of the invention, the first semiconductor layer 7 shown in FIG. 5 is made of a direct gap semiconductor that is a semiconductor selected from the group consisting of InAs, CuInSe₂, Cu(InGa)Se₂, CuInS, GaAs, InGaP, and CdTe that exhibit n-type conductivity. The second semiconductor layer 8 is formed on the first semiconductor layer 7 made of such a direct gap semiconductor. The second semiconductor layer 8 is made of a semiconductor selected from the group consisting of AlGaAs, CuInSe₂, Cu(InGa) Se₂, GaAs, AlGaP, and CdTe that exhibit p-type conductivity and compound semiconductors similar to those. A pn junction structure is formed in this manner.

Where amorphous semiconductors are used as the first semiconductor layer 7 and the second semiconductor layer 8, a pin junction structure may be formed by forming an i-type semiconductor layer 69 between a first semiconductor layer 68 and the second semiconductor layer 70 (described later; see FIG. 15).

Next, a method for producing the assembly 4 of the photoelectric conversion elements 31 (see FIG. 5) and the support 3 (see FIG. 1) will be described.

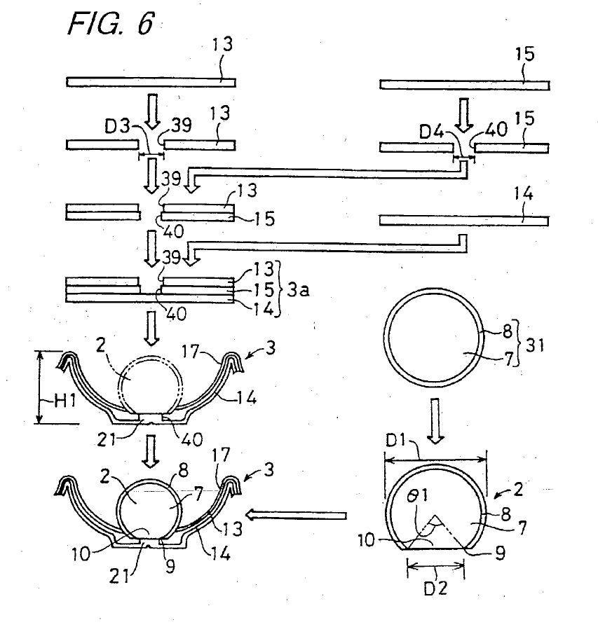

FIG. 6 is a sectional view showing a method for producing the assembly 4 of the photoelectric conversion elements 2 and the support 3. After the production of the spherical photoelectric conversion elements 31 shown in FIG. 5, the photoelectric conversion elements 31 are cut to provide the photoelectric conversion elements 2, as shown in FIG. 6. In each of resulting photoelectric conversion elements 2, as shown in FIG. 6, a portion 10 of the first semiconductor layer 7 is exposed through an opening 9 of the second semiconductor layer 8. The opening 9 has such a shape as would be obtained by cutting the photoelectric conversion elements 31 by a plane, and has a central angle θ1 that is less than 180°. The central angle θ1 may be in a range of 45° to 90°, for example. It is preferable that the central angle θ1 be in a range of 60° to 90°. The outer diameter D1 of each photoelectric conversion element 31 may be in a range of 0.5 mm to 2.0 mm, for example. It is preferable that the outer diameter D1 be about 0.762 mm. In FIG. 6, symbol D2 represents the inner diameter of the opening 9. The light-gathering ratio x=S1/S2 is in a range of 2 to 8, where S1 is the opening area of each recess 17 of the support 3 and S2 is the area of a cross-section including its center, of each photoelectric conversion element 2. It is preferable that the light-gathering ratio x be in a range of 4 to 6.

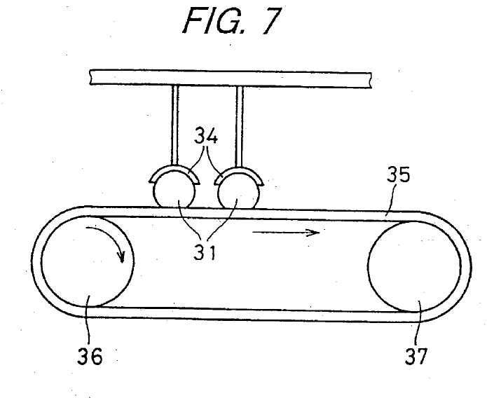

FIG. 7 is a sectional view showing a process for forming the opening 9 by cutting each spherical photoelectric conversion element 31. While the top portion of each of spherical photoelectric conversion elements 31 is vacuum-attracted by an attraction pad 34, the spherical photoelectric conversion elements 31 are ground by an endless-belt-shaped abrasive 35. The abrasive 35 is wound on rollers 36 and 37 and is thereby driven rotationally.

Returning to FIG. 6, the support 3 is produced in the following manner. A first conductor 13 made of aluminum foil is prepared and connection holes 39 are formed therein. The inner diameter D3 of each connection hole 39 is set smaller than the outer diameter D1 of each photoelectric conversion element 2 and greater than the inner diameter D2 of the opening 9 of the second semiconductor layer 8 (D1>D3>D2). A thin-plate-shaped insulator 15 is prepared and connection holes 40 are formed therein. The inner diameter D4 of each connection hole 40 is set smaller than the inner diameter D2 of the opening 9 of each photoelectric conversion element 2 (D2>D4). The first conductor 13 having the connection holes 39 is laid on and bonded to the insulator 15 having the connection holes 40, whereby the first conductor 13 and the insulator 15 are integrated with each other. Each pair of connection holes 39 and 40 shares a common axial line. The resulting structure is laid on and bonded to a second conductor 14, whereby second conductor 14 and the integral first conductor 13 and insulator 15 are integrated with each other to produce a flat support 3a. According to another embodiment of the invention, the first conductor 13 having the connection holes 39, the insulator 15 having the connection holes 40, and the second conductor 14 are laid one on another and bonded to each other at one time, thereby forming an integral structure. Each of the first conductor 13, the second conductor 14, and the insulator 15 may have a thickness of 60 μm, for example. The portion around the opening 9 of each photoelectric conversion element 2 fits into the connection hole 39 and is opposed to the connection hole 40 of the insulator 15. Alternatively, the portion around the opening 9 is placed on the first conductor 13 opposite the connection hole 39.

Reference is also made to FIG. 1. That portion of the outer surface of the second semiconductor layer 8 of each photoelectric conversion element 2 which is located above the opening 9 in FIG. 1 and surrounds the opening 9 is electrically connected to that portion of the first conductor 13 of the support 3 which is in the vicinity of the connection hole 39, that is, the inner circumferential face of the connection hole 39 or that portion of the first conductor 13 which is in the vicinity of and surrounds the connection hole 39. A connecting portion 44 (see FIG. 1) where the outer surface of the second semiconductor layer 8 is connected to the first conductor 13 is located on the opposite side (above in FIG. 1), to the second conductor 14, of a periphery 45 of the bottom surface of the photoelectric conversion element 2 containing the opening 9, whereby the first conductor 13 is inhibited from being electrically connected to the first semiconductor layer 7. The connecting portion 44 is parallel with the bottom surface of the photoelectric conversion element 2 containing the opening 9 and is closer to the opening 9 (i.e., lower in FIG. 1) than an imaginary plane 47 passing through the center 46 of the photoelectric conversion element 2 is.

Next, the flat support 3a is subjected to plastic deformation, whereby a plurality of recesses 17 are arranged adjacent to each other. The second conductor 14 is so deformed that it projects upward (in FIG. 6) through the connection hole 40 of the insulator 15, i.e., it penetrates through the connection hole 40 and protrudes thereon, to become connecting portions 21. The resulting support 3 has a height H1 of about 1 mm, for example.

The step of electrically connecting the first semiconductor layers 7 to the second conductor 14 and the step of electrically connecting the second semiconductor layers 8 to the first conductor 13 is performed either sequentially (either step is performed first) or simultaneously.

The photoelectric conversion elements 2 each having the opening 9 are accommodated in the respective recesses 17 thus formed.

According to another embodiment of the invention, the support 3 is produced in the following manner. After the 3-layer structure of the first conductor 13, the insulator 15, and the second conductor 14 is plastically deformed so as to form recesses 17, connection holes 39 and 40 are formed in the first conductor 13 and the insulator 15, respectively, by using two kinds of laser light.

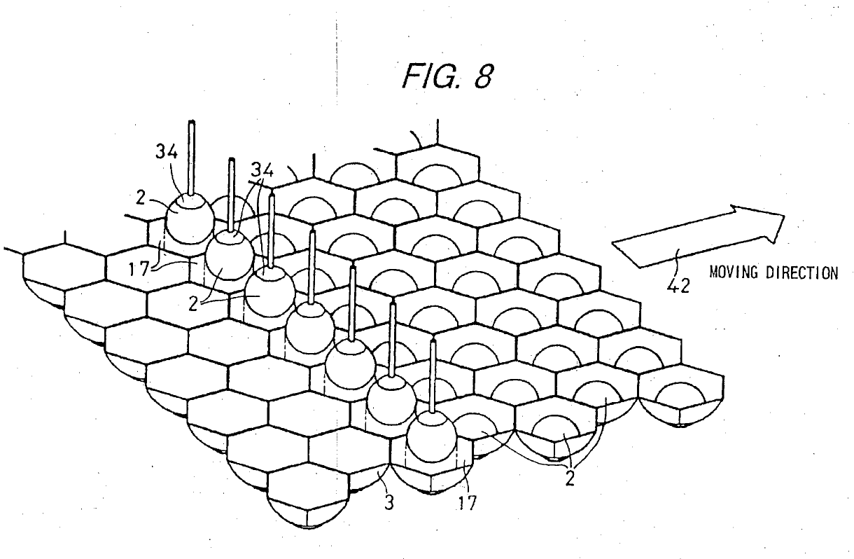

FIG. 8 is a simplified perspective view showing a process for putting the photoelectric conversion elements 2 in the respective recesses 17 of the support 3. A set of photoelectric conversion elements 2 produced by cutting photoelectric conversion elements 31 in a state that they are vacuum-attracted by the attraction pads 34 is transported with the openings 9 kept down and put in respective recesses 17 of the support 3. For example, 100 attraction pads 34 are arranged in line. After the set of photoelectric conversion elements 2 is put in the respective recesses 17 by means of the attraction pads 34, the support 3 is moved in a direction 42 by a distance that is equal to one pitch of the recesses 17, another set of photoelectric conversion elements 2 is put in new recesses 17 by using the attraction pads 34 in the same manner as described above. Photoelectric conversion elements 2 are put in all the recesses 17 by repeating the above operation. Then, the operation of electrically connecting each photoelectric conversion element 2 to the support 3 is performed at the bottom of each recess 17.

The first semiconductor layer 7 of each photoelectric conversion element 2 is exposed through the opening 9 and is electrically connected to the connecting portion 21 through the connection hole 40 of the second conductor 14. The portion, above the opening 9, of the outer surface of the second semiconductor layer 8 of each photoelectric conversion element 2 is electrically connected to that portion of the first conductor 13 which is in the vicinity of the connection hole 39. The first semiconductor layer 7 and the second semiconductor layer 8 of each photoelectric conversion element 2 may be connected electrically to the second conductor 14 and the first conductor 13, respectively, by using laser light (formation of an eutectic), conductive paste, or a metal bump. In this manner, the electrical connection is made without using lead-containing solder, which is preferable in terms of the environmental protection.

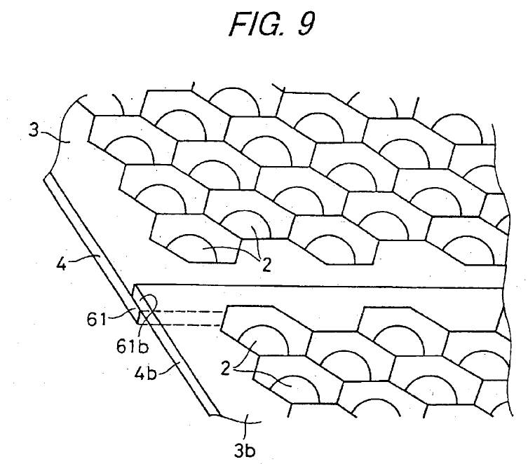

FIG. 9 is a perspective view showing how assemblies 4 and 4b of the photoelectric conversion elements 2 and the support 3 are connected to each other. The assemblies 4 and 4b are electrically connected to each other at their flat peripheral portions 61 and 61b extending outward.

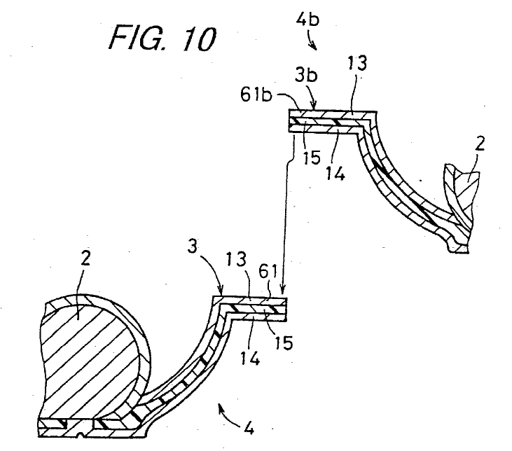

FIG. 10 is an exploded sectional view of the peripheral portions 61 and 61b and their vicinities of the assemblies 4 and 4b shown in FIG. 9. The second conductor 14 of the support 3b of the one assembly 4b is laid on, electrically connected to, and fixed to the first conductor 13 of the support 3 of the other assembly 4. In this manner, photoelectromotive forces, generated by the photoelectric conversion elements 2, of the assemblies 4, 4b, . . . are connected to each other in series, whereby a desired high voltage can be output.

FIG. 11 is a simplified side view showing how assemblies 4, 4b, and 4c are electrically connected to each other. The peripheral portion 61b of the assembly 4b is laid on and electrically connected to the peripheral portion 61 of the assembly 4 in the above-described manner. Further, the peripheral portion 61c of the assembly 4c is laid on and electrically connected to the peripheral portion 61b1 (located on the opposite side to the peripheral portion 61b) of the assembly 4b. In the structure of FIG. 11, the one peripheral portion 61b of the assembly 4b is located above the peripheral portion 61 of the assembly 4 and the other peripheral portion 61b1 of the assembly 4b is located below the peripheral portion 61c of the assembly 4c. In this manner, the assemblies are connected to each other in such a manner that the two peripheral portions of each assembly are located above and below the two adjacent assemblies, respectively, to thereby form a two-step structure. The length L61 of overlap, in the right-left direction in FIG. 11, between the peripheral portions 61 and 61b and between the peripheral portions 61b1 and 61c may be set at 1 mm, for example.

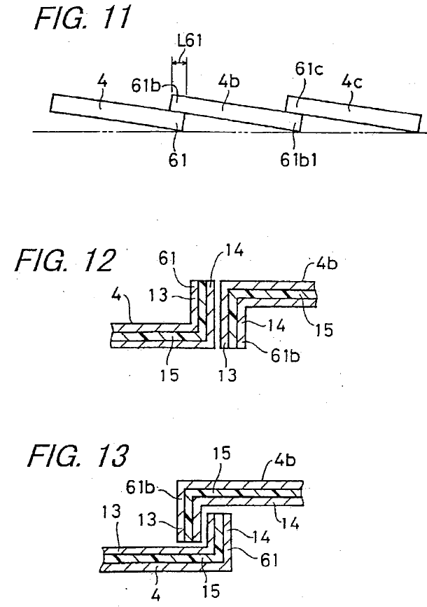

FIG. 12 is a sectional view showing an electrical connection structure of assemblies 4 and 4b that are adjacent to each other according to another embodiment of the invention. The peripheral portion 61 of the one assembly 4 projects upward and the peripheral portion 61b of the other assembly 4b projects downward. The second conductor 14 of the peripheral portion 61 is electrically connected to the first conductor 13 of the peripheral portion 61b.

FIG. 13 is a sectional view showing an electrical connection structure of assemblies 4 and 4b that are adjacent to each other according to still another embodiment of the invention. This embodiment is similar to the embodiment of FIG. 12 and is different from the latter in that the first conductor 13 of the peripheral portion 61 (projecting upward) of the assembly 4 is electrically connected to the second conductor 14 of the peripheral portion 61b (projecting downward) of the assembly 4b. The connection structures of FIGS. 12 and 13 make it possible to make the recesses 17 of the supports 3 and 3b closer to each other and thereby arrange as many recesses 17 and photoelectric conversion elements 2 as possible in a limited area.

Reference is now made to FIG. 14, which shows a plurality of generally spherical photoelectric conversion elements 2 forming part of an alternative embodiment of a photovoltaic apparatus in accordance with the present invention. Each of the photoelectric conversion elements 2 includes the first semiconductor layer and the second semiconductor layer that differs from the first semiconductor layer and surrounds the first semiconductor layer. It will be understood that the first and second semiconductor layers form a p-n junction therebetween for generating photoelectromotive force therebetween, with the application of incident light. The spherical semiconductor elements 2 shown in FIG. 14 are clearly closely packed together in a dense array.

Referring to FIG. 15, the generally spherical photoelectric conversion elements 2 are mounted on the first conductor 13 of the support. In the present embodiment, the first conductor 13 is a perforated aluminum foil. Each of the semiconductor elements 2 are bonded into the perforation holes in the aluminum foil such that ohmic contact is created between the aluminum foil and the and the second semiconductor layer of the photoelectric conversion elements 2. The first semiconductor layer is exposed (not shown) on the underside of the first conductor 13 thereby allowing ohmic contact to be made to the first semiconductor of each generally spherical photoelectric conversion element 2. The first semiconductor layer is exposed by any suitable method such as grinding or etching of the photoelectric conversion elements 2. It will be understood by those skilled in the art that the first semiconductor is in ohmic contact with a second conductor (not shown) of the support. Thus, ohmic contact is made to each side of the p-n junction of the generally spherical photoelectric conversion elements 2.

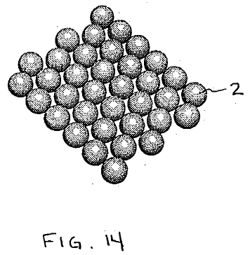

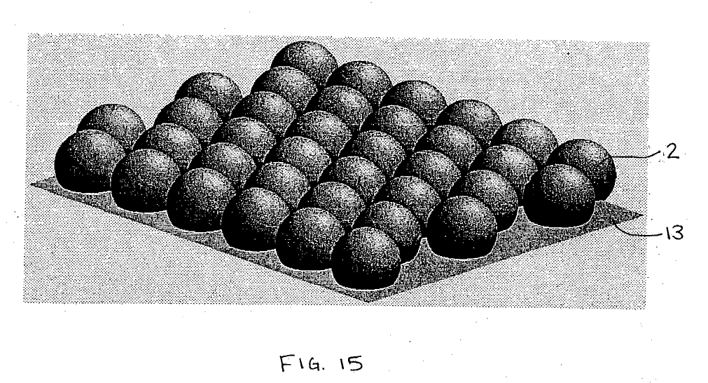

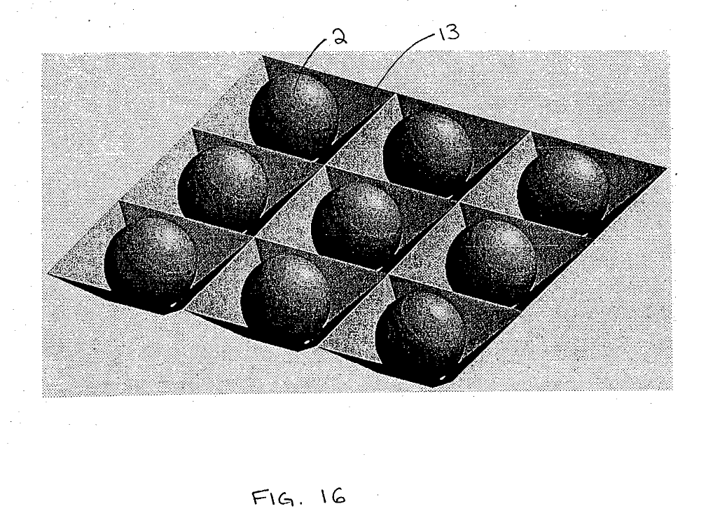

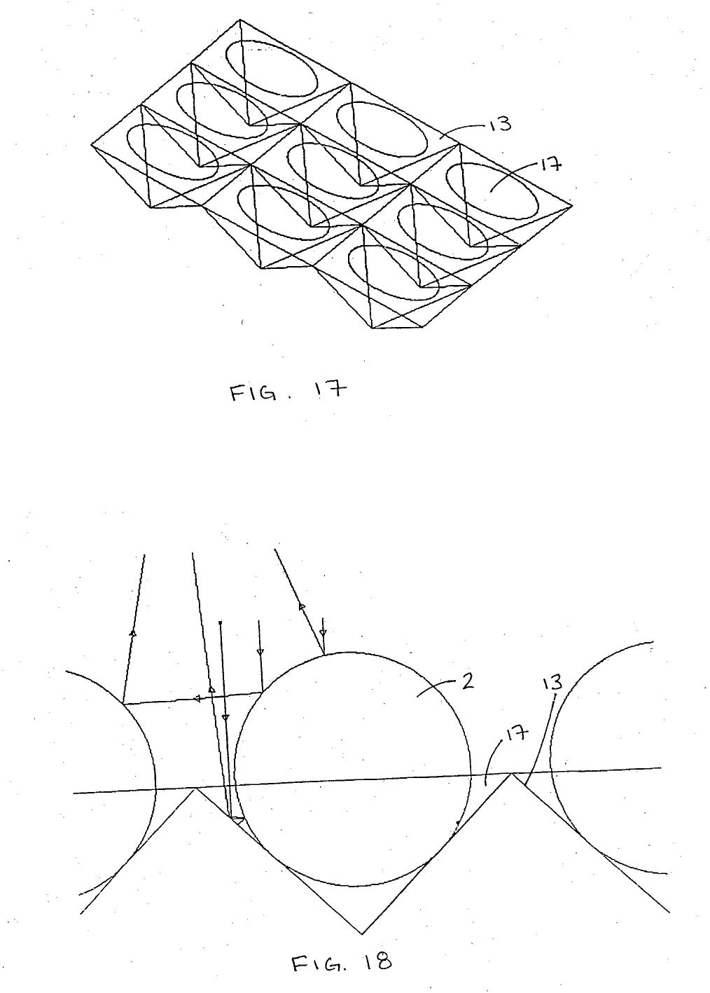

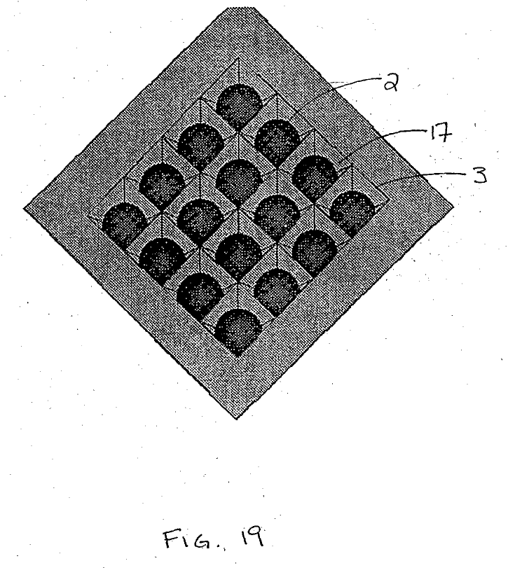

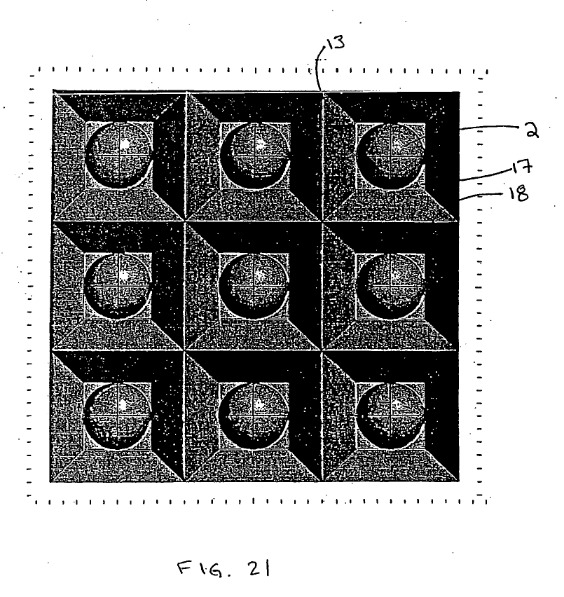

Reference is now made to FIGS. 5, 16 and 19, which show the generally spherical photoelectric conversion elements 2 mounted on a first conductor 13 of a support, according to another embodiment of a photovoltaic apparatus in accordance with the present invention. In the present embodiment, the first conductor 13 is a perforated aluminum foil shaped to form an array of recesses 17, each recess 17 narrowing towards a bottom thereof. Each recess 17 includes an opening 18 that is polygonal in shape. In the present embodiment, each opening is square in shape and each recess 17 narrows as the four sides of the square narrow towards the bottom. FIG. 17 shows a perspective view including hidden detail of the first conductor 13 of the support. As shown, the first conductor 13 includes narrowing recesses 17, each with openings in the shape of a square.

Referring again to FIG. 16, each of the semiconductor photoelectric conversion elements 2 are bonded into perforation holes in the first conductor 13 such that ohmic contact is created between the first conductor 13 and the second semiconductor layer of the photoelectric conversion elements 2. Thus, each of the photoelectric conversion elements 2 is mounted in a perforation hole in a respective one of the recesses 17. The first semiconductor layer is exposed (not shown) on the underside of the first conductor 13, thereby allowing ohmic contact to be made to the first semiconductor of each generally spherical photoelectric conversion element 2. Thus, ohmic contact is made to each side of the p-n junction of the generally spherical photoelectric conversion elements 2. The narrowing recesses 17 of the first conductor 13 serve to reflect incident light towards the photoelectric conversion elements 2.

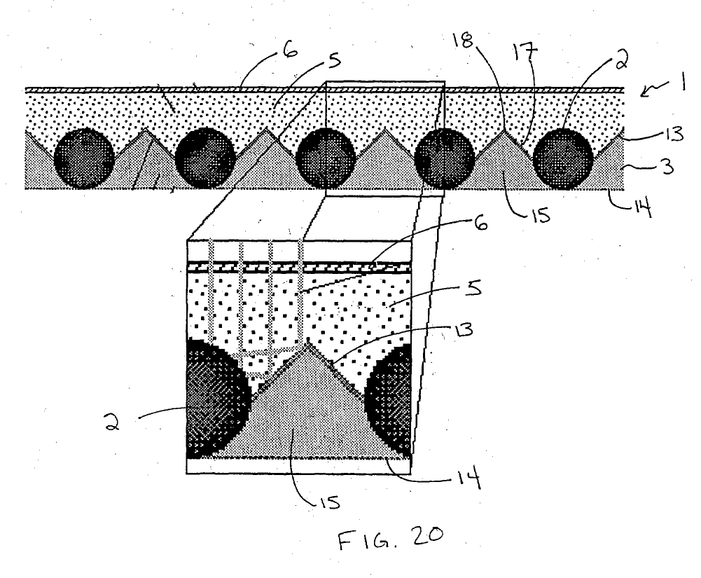

FIG. 18 is a section side view of the photoelectric conversion elements 2 in respective recesses 17 of the first conductor 13 of FIG. 16, showing incident light reflected from the first conductor 13 towards the spherical elements 2. FIG. 17 is shown for exemplary purposes to indicate the reflection of incident light only.

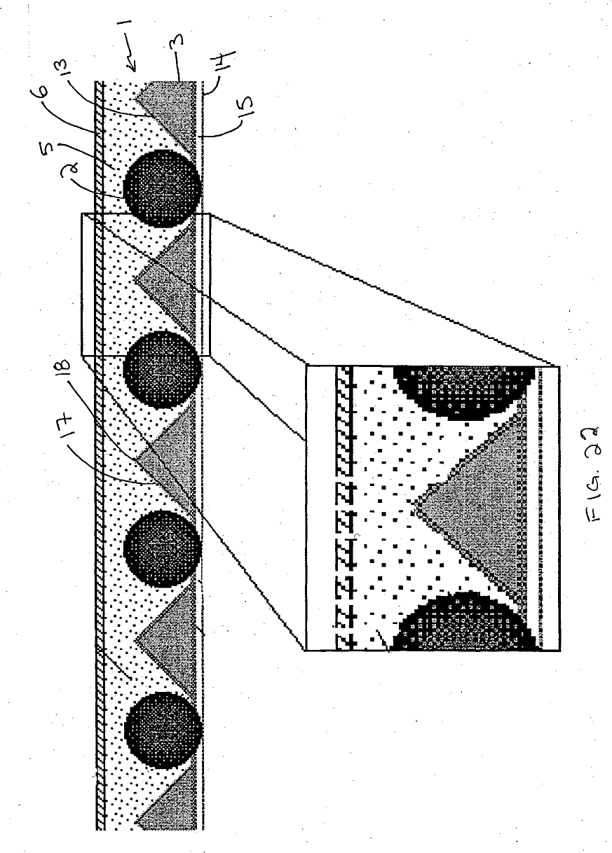

Referring now to FIG. 20, an enlarged sectional side view of the photovoltaic apparatus 1, according to the embodiment of FIG. 16, is shown. The photovoltaic apparatus 1 includes the generally spherical photoelectric conversion elements 2 described hereinabove and the support 3. The photoelectric conversion elements 2 are mounted on the support 3 and are buried in the filler layer 5 of transparent synthetic resin material such as EVA (ethylene vinyl actetate) or PVB (poly-vinyl butyral). The transparent protective sheet 6 formed of, for example, polycarbonate or the like, is provided on the light source (e.g. sunlight) side of the filler layer 5.

As described hereinabove, each of the photoelectric conversion elements 2 includes a first semiconductor layer and a second semiconductor layer that differs from the first semiconductor layer and surrounds the first semiconductor layer, forming a p-n junction therebetween for generating photoelectromotive force, with the application of incident light.

The support 3 includes the first conductor 13, described above, and the second conductor 14. The first and second conductors 13, 14, respectively are electrically insulated from each other by the insulator 15. The recesses 17, as described above, are adjacent each other in an array, with the inside surfaces of the recesses 17 formed by the first conductor 13. The photoelectric conversion elements 2 are bonded in perforation holes in the recesses 17 of the first conductor 13 such that ohmic contact is created between the first conductor 13 and the second semiconductor layer of the photoelectric conversion elements 2. The first semiconductor layer is exposed on the underside of the first conductor 13 and the second conductor 14 of the support 3 is in ohmic contact with the first semiconductor of each generally spherical element 2. Thus, ohmic contact is made to each side of the p-n junction of the generally spherical photoelectric conversion elements 2. As shown in FIG. 20, incident light that passes through the protective sheet 6 and the filler layer 5 and strikes the inside surface of one of the recesses 17, is reflected towards the photoelectric conversion elements 2.

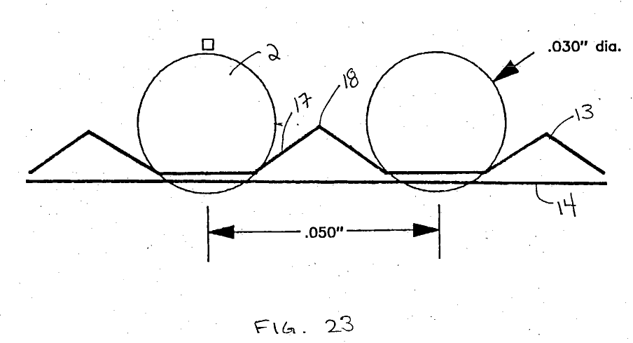

Reference is now made to FIG. 21, which shows the generally spherical photoelectric conversion elements 2 mounted to the first conductor 13, in accordance with another embodiment of a photovoltaic apparatus in accordance with the present invention. In the present embodiment, the first conductor 13 is a perforated aluminum foil shaped to form an array of recesses 17, similar to FIG. 16. Each recess 17 includes an opening 18 that is square in shape and narrows as the four sides of the square narrows towards the bottom. In contrast with the embodiment of FIG. 16, the present embodiment includes a flat bottom section in each of the recesses 17. Each flat bottom section includes a perforation hole in which the generally photoelectric conversion elements 2 are bonded.

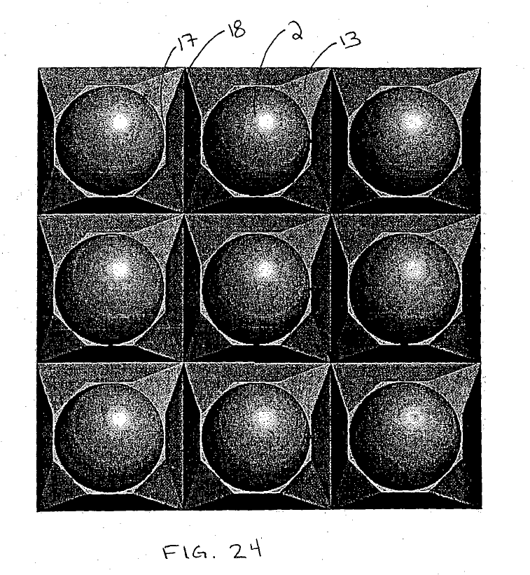

Referring now to FIG. 22 an enlarged sectional side view of a photovoltaic apparatus 1, according to the embodiment of FIG. 21, is shown. The photovoltaic apparatus 1 includes the generally spherical photoelectric conversion elements 2 described above and the support 3. As in the embodiment of FIG. 20, the photoelectric conversion elements 2 are mounted on the support 3 and are buried in the filler layer 5 of transparent synthetic resin material such as EVA (ethylene vinyl actetate) or PVB (poly-vinyl butyral). The transparent protective sheet 6 formed of, for example, polycarbonate or the like, is provided on a light source (e.g. sunlight) side of the filler layer.

Similar to the embodiment of FIG. 20, each of the photoelectric conversion elements 2 includes the first semiconductor layer and the second semiconductor layer that differs from the first semiconductor layer and surrounds the first semiconductor layer. Thus the p-n junction is formed between the first and second semiconductor layers for generating photoelectromotive force therebetween, with the application of incident light.

The support 3 includes the first conductor 13, described above, and the second conductor 14. The first and second conductors 13, 14, respectively are electrically insulated from each other by the insulator 15. The recesses 17, as described above, are adjacent each other in an array, with the inside surfaces of the recesses 17 formed by the first conductor 13. The photoelectric conversion elements 2 are bonded in perforation holes in the recesses 17 of the first conductor 13, such that ohmic contact is created between the first conductor 13 and the second semiconductor layer of the photoelectric conversion elements 2. The first semiconductor layer is exposed on the underside of the first conductor 13 and the second conductor 14 of the support 14 is in ohmic contact with the first semiconductor of each generally spherical element 2. Thus, ohmic contact is made to each side of the p-n junction of the generally spherical photoelectric conversion elements 2.

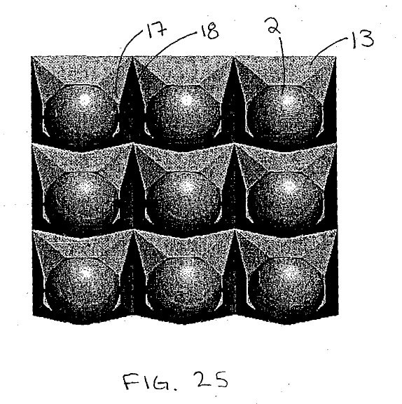

FIG. 23 shows a sectional side view of a portion of the photovoltaic apparatus of FIG. 22. In the present embodiment, the center to center spacing of the generally spherical photoelectric conversion elements 2 is about 0.050 inches (1.27 mm) and the diameter of the generally spherical photoelectric conversion elements 2 is about 0.03 inches (0.762 mm).

The first conductor 13 is shaped by forming tapered holes in the form of recesses 17 with perforation holes in the bottom thereof, into aluminum foil that is on the order of about 8 to 10 mils (0.2 mm to 0.254 mm) in thickness.

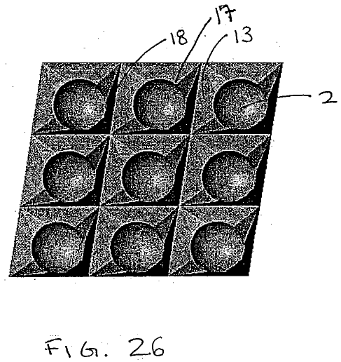

Referring to FIGS. 24 and 25, there is shown the generally spherical photoelectric conversion elements 2 mounted on the first conductor 13, according to yet another embodiment of a photovoltaic apparatus in accordance with the present invention. In the present embodiment, the first conductor 13 is a perforated aluminum foil shaped to form an array of recesses 17. Each recess 17 narrows towards the bottom thereof. Each recess 17 includes an opening 18 that is square in shape and narrows or tapers inwardly. Rather than four sides tapering inwardly towards the bottom of the recess 17 as in the previous embodiments, eight sides taper inwardly from the square opening, thereby providing more facets for reflecting light towards the generally spherical photoelectric conversion elements 2.

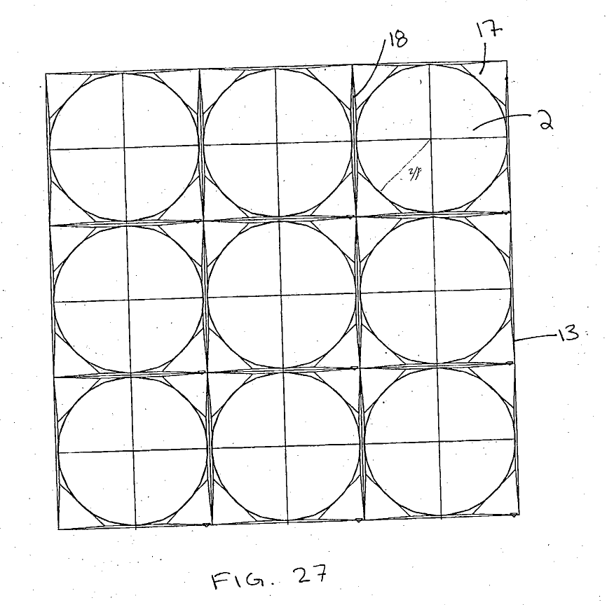

FIGS. 26 and 27 show perspective and top views of the generally spherical photoelectric conversion elements 2 mounted on the first conductor 13, similar to the embodiment of FIG. 25, but with a smaller sphere to sphere spacing.

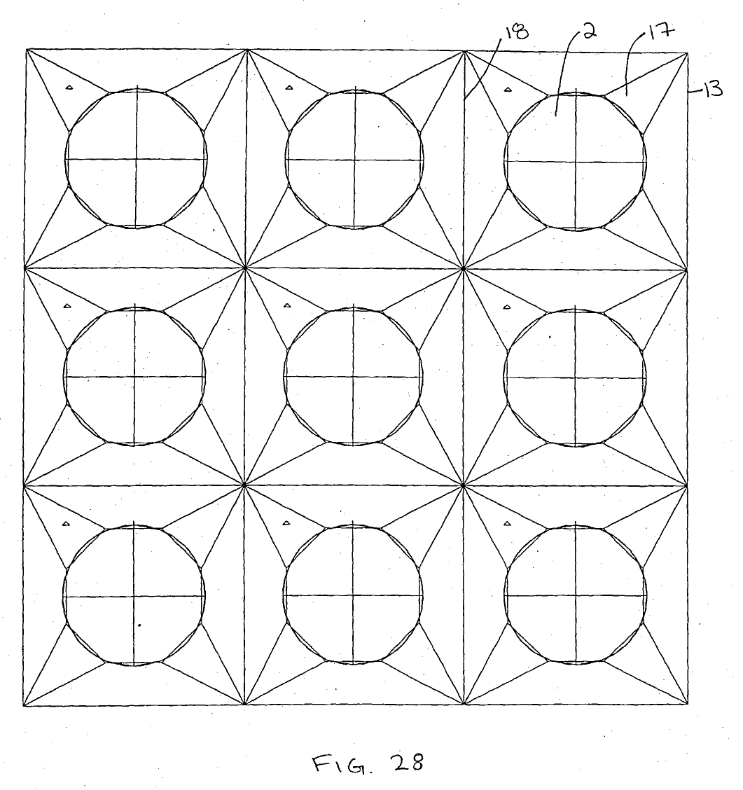

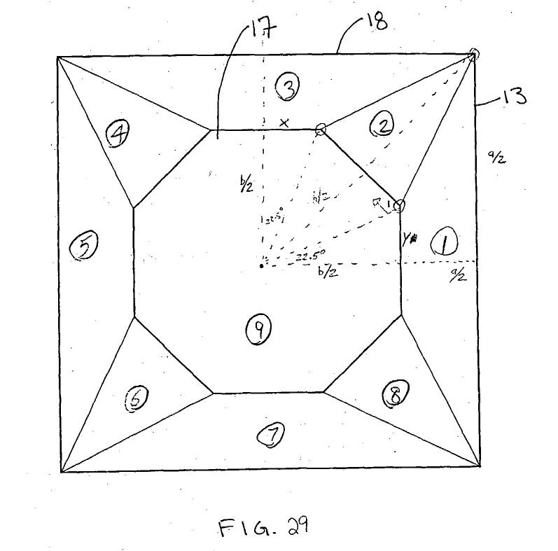

FIG. 28 shows a top view of the generally spherical photoelectric conversion elements 2 mounted on the first conductor 13 of FIG. 25. Although the shape of the first conductor 13 shown in FIG. 28 is similar to the shape of the first conductor 13 shown in FIG. 27, the density of generally spherical photoelectric conversion elements 1 is different. Thus, the density of recesses 17 differs between the embodiments of FIGS. 27 and 28.

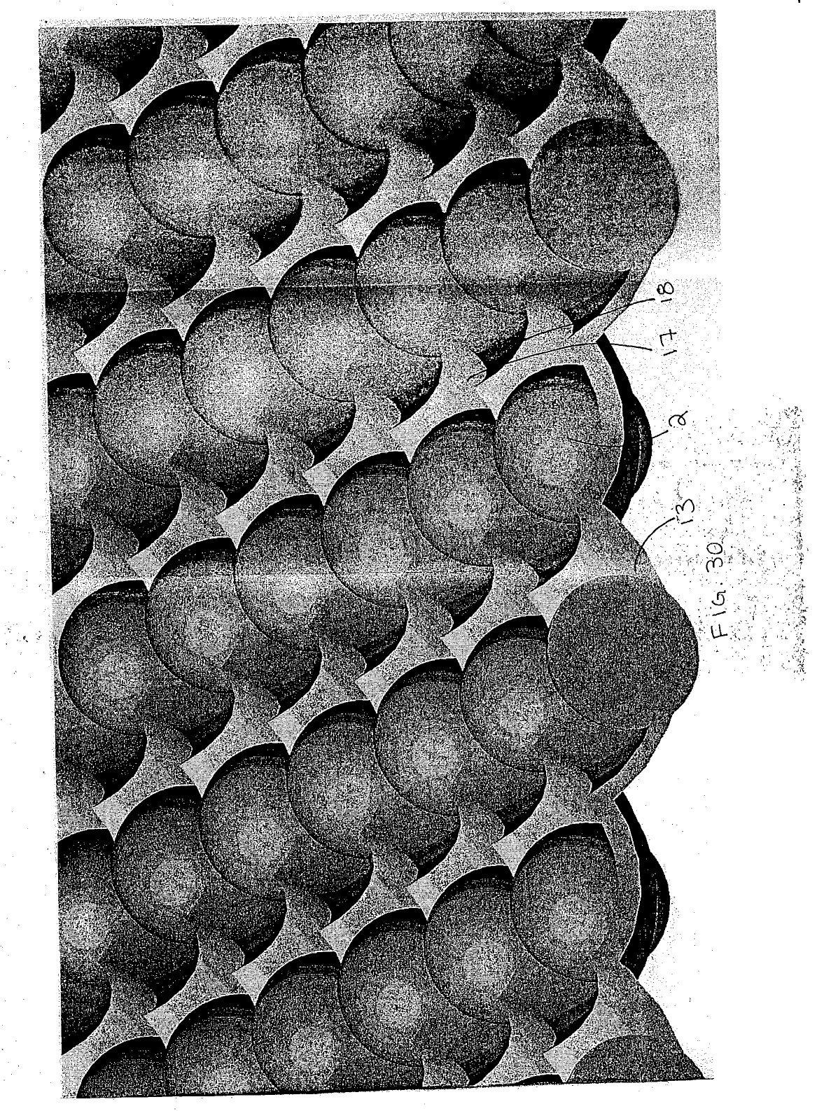

FIG. 29 shows a top view of one of the recesses 17 of the first conductor 13 of FIG. 24. As shown, eight sides of each recess 17 taper inwardly from the generally square opening 18 to a flat octagonal bottom. It will be appreciated that, although not shown, the generally spherical perforation hole is provided in the flat octagonal bottom, for mounting the generally spherical photoelectric conversion element 2 (not shown) therein.

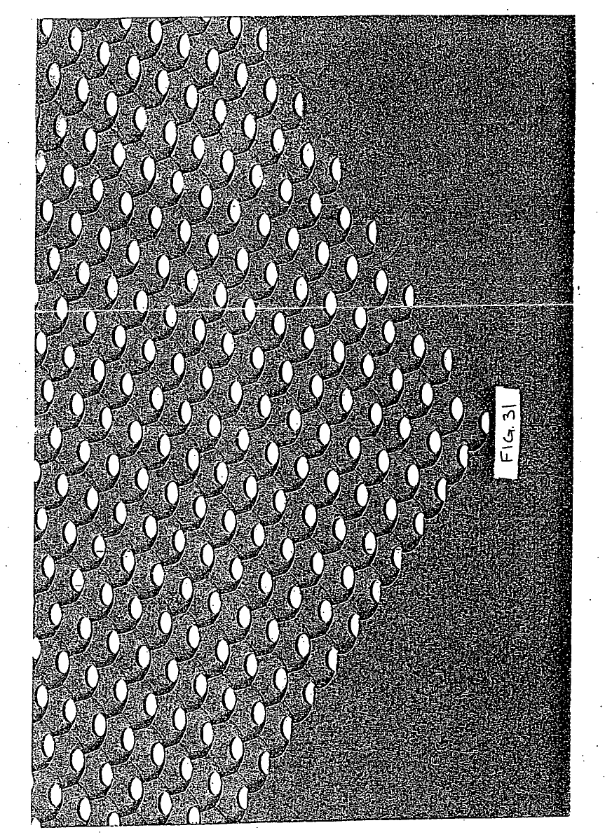

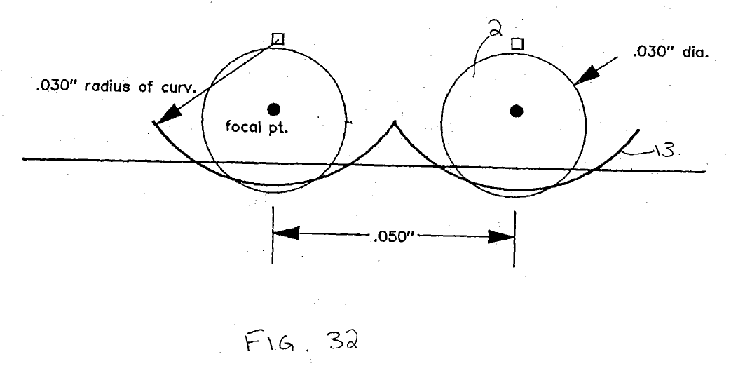

Reference is now made to FIG. 30, which shows the generally spherical photoelectric conversion elements 2 mounted on the first conductor 13, in accordance with yet another embodiment of a photovoltaic apparatus in accordance with the present invention. The first conductor 13 is a perforated aluminum foil shaped to form an array of recesses 17. In the present embodiment, each recess 17 includes an opening defined by six curved edges and is generally spherical in shape. Each recess 17 includes the perforation hole in which the generally spherical photoelectric conversion elements 2 are bonded. Thus, each generally spherical photoelectric conversion element 2 extends partially through the first conductor 13. FIG. 31 shows a top perspective view of the first conductor 13 of FIG. 30, without the photoelectric conversion elements 2 disposed in the recesses 17 therein.

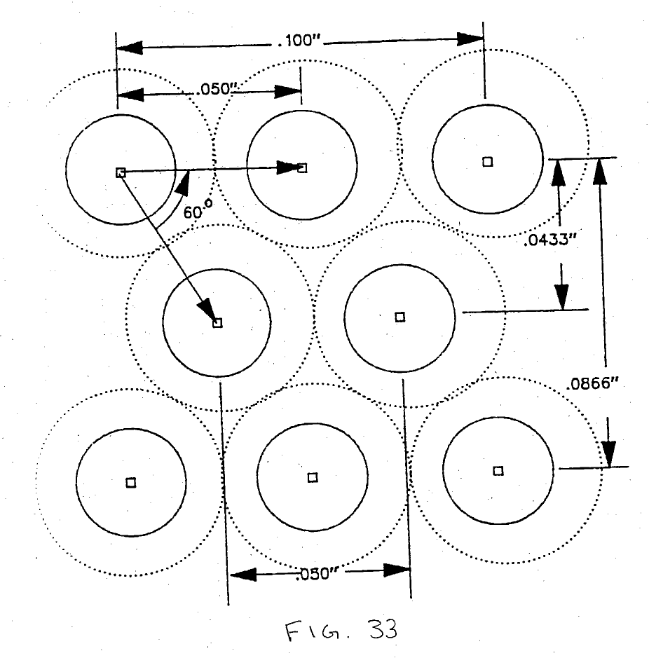

FIG. 32 shows a sectional side view of the generally spherical photoelectric conversion elements 2 mounted on the first conductor 13 of FIG. 30. In the present embodiment, the spacing between the centers of the generally spherical photovoltaic conversion elements 2 is about 0.050 inches (1.27 mm) and the diameter of the generally spherical photovoltaic conversion elements 2 is about 0.03 inches (0.762 mm). FIG. 33 is a top view showing the center to center spacing of the perforation holes of the first conductor 13 of FIG. 32. FIG. 33 is shown for exemplary purposes to show the perforation hole spacing only. As shown, the center to center spacing of adjacent perforation holes is about 0.050 inches (1.27 mm). The angular arrangement from horizontally adjacent perforation holes to vertically adjacent perforation holes, is about 60 degrees. Each perforated hole is about 0.02 inches (0.51 mm) diameter.

The invention may be embodied in other specific forms without departing from the spirit or essential characteristics thereof. The present embodiments are therefore to be considered in all respects as illustrative and not restrictive, the scope of the invention being indicated by the appended claims rather than by the foregoing description and all changes which come within the meaning and the range of equivalency of the claims are therefore intended to be embraced therein.

What is claimed is:

1. A photovoltaic apparatus comprising:
(a) a plurality of photoelectric conversion elements, each being of an approximately spherical shape and including a first semiconductor layer and a second semiconductor layer which is located outside the first semiconductor layer, for generating photoelectromotive force between the first and second semiconductor layers, the second semiconductor layer having an opening through which a portion of the first semiconductor layer is exposed; and
(b) a support including a first conductor, a second conductor, and an insulator disposed between the first and second conductors for electrically insulating the first and second conductors from each other, the support having a plurality of recesses which are arranged adjacent to each other and of which inside surfaces are constituted by the first conductor or a coating formed thereon, the photoelectric conversion elements being disposed in the respective recesses so that the photoelectric conversion elements are illuminated with light reflected by part of the first conductor or coating formed thereon which constitutes the recess, the first conductor being electrically connected to the second semiconductor layers of the photoelectric conversion elements, and the second conductor being electrically connected to the exposed portions of the first semiconductor layers.

2. The photovoltaic apparatus of claim 1, wherein the photoelectric conversion elements have an outer diameter of 0.5 mm to 2.0 mm.

3. The photovoltaic apparatus of claim 1, wherein the opening of the second semiconductor layer has a central angle .theta.1 of 45.degree. to 90.degree.

4. The photovoltaic apparatus of claim 1, wherein the recesses of the support have respective openings of a polygon of which ones adjacent to each other are continuous, each of the recesses narrows toward a bottom thereof, and the first semiconductor layer and second semiconductor layer of each of the photoelectric conversion elements are electrically connected to the second conductor and the first conductor, respectively, at the bottom or in a vicinity thereof of the recess.

5. The photovoltaic apparatus of claim 4, wherein the first conductor is provided with a circular first connection hole formed at the bottom or in a vicinity thereof of the recess and the insulator is provided with a circular second connection hole having a common axial line with the first connection hole, a portion of the photoelectric conversion element in a vicinity of the opening of the second semiconductor-layer fits in the first connection hole and an outer surface portion above the opening of the second semiconductor layer is electrically connected to an end face of the first connection hole of the first conductor or to a portion thereof in the vicinity of the end face, and the exposed portion of the first semiconductor layer of the photoelectric conversion element is electrically connected to the second conductor through the second connection hole.

6. The photovoltaic apparatus of claim 5, wherein an outer diameter D1 of the photoelectric conversion elements, an inner diameter D2 of the openings of the second semiconductor layers, and an inner diameter D3 of the first connection holes, and an inner diameter D4 of the second connection holes satisfy a relationship D1>D3>D2>D4.

7. The photovoltaic apparatus of claim 1, wherein a light-gathering ratio x which equals to S1/S2 is selected to be in a range of 2 to 8, wherein S1 is an opening area of each of the recesses of the support and S2 is an area of a cross-section of the photoelectric conversion elements including a center thereof.

8. A photovoltaic apparatus comprising:
(a) a plurality of photoelectric conversion elements, each being of an approximately spherical shape and including a first semiconductor layer and a second semiconductor layer which is located outside the first semiconductor layer, for generating photoelectromotive force between the first and second semiconductor layers, the second semiconductor layer having an opening through which a portion of the first semiconductor layer is exposed; and
(b) a support including a first conductor, a second conductor, and an insulator disposed between the first and second conductors for electrically insulating the first and second conductors from each other, the support having a plurality of recesses which are arranged adjacent to each other and of which inside surfaces are constituted by the first conductor or a coating formed thereon, the photoelectric conversion elements being disposed in the respective recesses so that the photoelectric conversion elements are illuminated with light reflected by part of the first conductor or coating formed thereon which constitutes the recess, the first conductor being electrically connected to the second semiconductor layers of the photoelectric conversion elements, and the second conductor being electrically connected to the exposed portions of the first semiconductor layers, wherein each of the photoelectric conversion elements has an outer diameter of 0.5 mm to 2 mm, and a light-gathering ratio x which equals to S1/S2 is selected to be in a range of 2 to 8, wherein S1 is an opening area of each of the recesses of the support and S2 is an area of a cross-section of the photoelectric conversion elements including a center thereof.

9. A photovoltaic apparatus comprising:
(a) a plurality of photoelectric conversion elements, each being of an approximately spherical shape and including a first semiconductor layer and a second semiconductor layer which is located outside the first semiconductor layer, for generating photoelectromotive force between the first and second semiconductor layers, the second semiconductor layer having an opening through which a portion of the first semiconductor layer is exposed; and
(b) a support including a first conductor, a second conductor, and an insulator disposed between the first and second conductors for electrically insulating the first and second conductors from each other, the support having a plurality of recesses which are arranged adjacent to each other and of which inside surfaces are constituted by the first conductor or a coating formed thereon, the photoelectric conversion elements being disposed in the respective recesses so that the photoelectric conversion elements are illuminated with light reflected by part of the first conductor or coating formed thereon which constitutes the recess, the first conductor being electrically connected to the second semiconductor layers of the photoelectric conversion elements, and the second conductor being electrically connected to the exposed portions of the first semiconductor layers, wherein each of the photoelectric conversion elements has an outer diameter of 0.8 mm to 1.2 mm, and a light-gathering ratio x which equals to S1/S2 is selected to be in a range of 4 to 6, wherein S1 is an opening area of each of the recesses of the support and S2 is an area of a cross-section of the photoelectric conversion elements including a center thereof.

10. The photovoltaic apparatus of claim 1, wherein the photoelectric conversion elements have a pn junction in such a manner that the second semiconductor layer of one conductivity type having a wider optical band gap than the first semiconductor layer having the other conductivity type does is formed outside the first semiconductor layer.

11. The photovoltaic apparatus of claim 1, wherein the photoelectric conversion elements have a pin junction in such a manner that the first semiconductor layer having one conductivity type, an amorphous intrinsic semiconductor layer, and an amorphous second semiconductor layer of the other conductivity type having a wider optical band gap than the first semiconductor layer does are arranged outward in this order.

12. The photovoltaic apparatus of claim 10, wherein the first semiconductor layer and the second semiconductor layer are made of n-type silicon and p-type amorphous SiC, respectively.

13. The photovoltaic apparatus of claim 12, wherein the n-type silicon of which the first semiconductor layer is made is n-type single-crystal silicon or n-type microcrystalline (.mu.c) silicon.

14. The photovoltaic apparatus of claim 1, wherein the first semiconductor layer is a direct gap semiconductor layer.

15. The photovoltaic apparatus of claim 14, wherein the direct gap semiconductor layer is made of a semiconductor selected from the group consisting of InAs, GaSb, CuInSe.sub.2, Cu(InGa) Se.sub.2, CuInS, GaAs, InGaP, and CdTe.
